(19) United States
(12) Patent Application Publication
(10) Pub. No.: US 2014/0014401 A1
(43) Pub. Date: Jan. 16, 2014

(54) CIRCUIT DEVICE AND METHOD FOR MAKING THE SAME

(71) Applicants: Pen-Yi LIAO, Taichung City (TW); Ming-Chun WU, Taichung City (TW); I-Lin TSENG, Taichung City (TW); Tsung-Han WU, Taichung City (TW); Jung-Chi LIN, Taichung City (TW)

(72) Inventors: Pen-Yi LIAO, Taichung City (TW); Ming-Chun WU, Taichung City (TW); I-Lin TSENG, Taichung City (TW); Tsung-Han WU, Taichung City (TW); Jung-Chi LIN, Taichung City (TW)

(73) Assignee: TAIWAN GREEN POINT ENTERPRISES CO., LTD., Taichung City (TW)

(21) Appl. No.: 13/547,454

(22) Filed: Jul. 12, 2012

(51) Int. Cl. H05K 1/09; H05K 3/00

(52) U.S. Cl. 174/257; 427/555

(57) ABSTRACT

A circuit device includes: a substrate having an insulative upper surface; a hydrophobic anti-plating layer of a hydrophobic material formed on the upper surface of the substrate and having at least one patterned through-hole for exposing a plating portion of the upper surface of the substrate; an active metal layer formed on the plating portion of the upper surface of the substrate and disposed in the patterned through-hole in the hydrophobic anti-plating layer; and an electroless deposited metal layer electroless deposited on the active metal layer.

### BACKGROUND OF THE INVENTION

1. Field of the Invention

The invention relates to a circuit device and a method for making the same, and more particularly to a circuit device including a hydrophobic anti-plating layer on an insulating substrate and a circuit pattern embedded in the hydrophobic anti-plating layer.

2. Description of the Related Art

U.S. Patent Application Publication No. 2010/0243149 discloses a circuit board including a first insulating resin layer, a second insulating resin layer laminated with the first insulating resin layer and formed with a pattern of holes, a patterned conductive paste layer formed on the first insulating resin layer and disposed within the holes in the second insulating resin layer, and a deposited metal layer formed on the patterned conductive paste layer. The patterned conductive paste layer is formed by applying a solvent-based paste material to designated regions of the first insulating resin layer using inkjet techniques, followed by drying and curing. The solvent-based paste material contains a dispersion solvent and fine particles of an active metal dispersed in the dispersion solvent. After formation of the patterned conductive paste layer, a non-hydrophobic insulating resin is laminated with the first insulating resin layer and covers the patterned conductive paste layer by thermal bonding, followed by forming trenches in the non-hydrophobic insulating resin so as to form the second insulating resin layer on the first insulating resin layer. The non-hydrophobic insulating resin has a high adherence to the conductive paste layer.

U.S. Pat. No. 4,865,873 discloses a method for making a circuit pattern on a substrate of a circuit board. The method includes forming an insulating layer on a substrate, forming a water-soluble layer on the insulating layer, forming a patterned hole extending through the water-soluble layer and the insulating layer by laser ablation, coating a catalyst layer on the water-soluble layer and a hole-defining wall of the patterned hole, electroless depositing a deposited metal layer on the catalyst layer in the patterned hole, and removing the water-soluble layer and the catalyst layer formed thereon such that the metal layer to serve as a circuit pattern in the patterned hole protrudes from the insulating layer.

Since the circuit pattern thus formed inevitably has a configuration protruding from the insulating layer, an adverse effect on assembly of the circuit device to an external device results. In addition, the method requires the use of a water-soluble layer and subsequent removal of the water-soluble layer to prevent formation of the deposited metal layer on an upper surface of the insulating layer from occurring.

### SUMMARY OF THE INVENTION

Therefore, an object of the present invention is to provide a circuit device that can overcome the aforesaid drawbacks associated with the prior art and that is easy to fabricate.

According to one aspect of the present invention, there is provided a circuit device that comprises: a substrate having an insulative upper surface; a hydrophobic anti-plating layer of a hydrophobic material formed on the upper surface of the substrate and having at least one patterned through-hole for exposing a plating portion of the upper surface of the substrate; an active metal layer formed on the plating portion of the upper surface of the substrate and disposed in the patterned through-hole in the hydrophobic anti-plating layer; and an electroless deposited metal layer electroless deposited on the active metal layer.

According to another aspect of the present invention, there is provided a method for making a circuit device. The method comprises: forming a hydrophobic anti-plating layer of a hydrophobic material on an insulative upper surface of a substrate; forming a patterned through-hole in the hydrophobic anti-plating layer by laser ablation such that the patterned through-hole exposes a plating portion of the upper surface of the substrate; bringing an assembly of the substrate and the patterned hydrophobic anti-plating layer into contact with an aqueous active metal solution such that only the plating portion of the upper surface of the substrate is wetted by the aqueous active metal solution, thereby forming an active metal layer on the plating portion of the upper surface of the substrate; and electroless depositing an electroless deposited metal layer on the active metal layer.

### BRIEF DESCRIPTION OF THE DRAWINGS

In drawings which illustrate embodiments of the invention,

FIGS. 1 to 7 are schematic diagrams illustrating consecutive steps of the preferred embodiment of a method of making a circuit device according to the present invention;

FIG. 8 is a perspective view of the preferred embodiment of a circuit device according to the present invention; and

FIG. 9 is a sectional view of the preferred embodiment shown in FIG. 8.

### DETAILED DESCRIPTION OF THE PREFERRED EMBODIMENTS

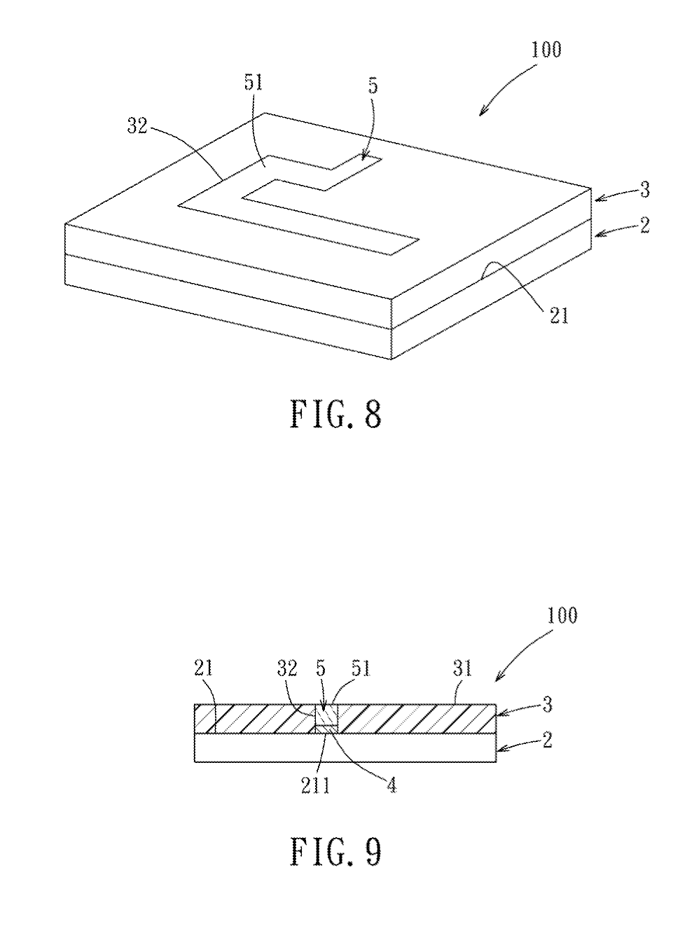

FIGS. 8 and 9 illustrate the preferred embodiment of a circuit device 100, such as an antenna, according to the present invention. The circuit device 100 includes: an insulating substrate 2 having an insulative upper surface 21; a hydrophobic anti-plating layer 3 of a hydrophobic material formed on the upper surface 21 of the substrate 2 and having an upper surface 31 distal from the upper surface 21 of the substrate 2 and at least one patterned through-hole 32 for exposing a plating portion 211 of the upper surface 21 of the substrate 2; an active metal layer 4 formed on the plating portion 211 of the upper surface 21 of the substrate 2 and disposed in the patterned through-hole 32 in the hydrophobic anti-plating layer 3; and an electroless deposited metal layer 5 electroless deposited on the active metal layer 4 and having an upper surface 51 disposed within the patterned through-hole 32 in the hydrophobic anti-plating layer 3 or substantially flush with a top end of the patterned through-hole 32. The electroless deposited metal layer 5 defines a circuit pattern on the substrate 2. Alternatively, the circuit pattern can further include an electroplating layer (not shown) that is electroplated on the electroless deposited metal layer 5.

In this embodiment, the upper surface 51 of the electroless deposited metal layer 5 substantially adjoins the upper surface 31 of the hydrophobic anti-plating layer 3 such that the upper surface 51 of the electroless deposited metal layer 5 and the upper surface 31 of the hydrophobic anti-plating layer 3 cooperatively forma continuous and smooth surface. The preferred embodiment can be modified such that the continuous and smooth surface may be curved or have round corners.

Preferably, the hydrophobic material is a hydrophobic resin selected from the group consisting of polycarbonate, poly-dimethylsiloxane adipamide, polypropylene, and combinations thereof. More preferably, the hydrophobic material is a hydrophobic resin selected from the group consisting of polycarbonate having a molecular weight ranging from 1000 to 4000, poly-dimethylsiloxane adipamide having a molecular weight ranging from 1000 to 4000, polypropylene having a molecular weight ranging from 1000 to 4000, and combinations thereof.

Alternatively, the hydrophobic material may be made from a wax material. Preferably, the wax material contains a wax and an inorganic oxide selected from the group consisting of silicon dioxide, titanium dioxide, magnesium oxide, zirconium dioxide and combinations thereof.

Preferably, the wax material contains 60-95 wt % of the wax and 5-40 wt % of the inorganic oxide.

Preferably, the wax has a melting point not less than 60° C.

Preferably, the substrate 2 is made from a material selected from the group consisting of polycarbonate, a combination of acryl resin and ABS resin, and a combination of polycarbonate and ABS resin.

Preferably, the active metal layer 4 is made from an active material containing an active metal selected from the group consisting of palladium, rhodium, platinum, iridium, osmium, gold, nickel, iron, and combinations thereof.

Preferably, the electroless deposited metal layer is made from a metal selected from the group consisting of copper, nickel, silver, and gold.

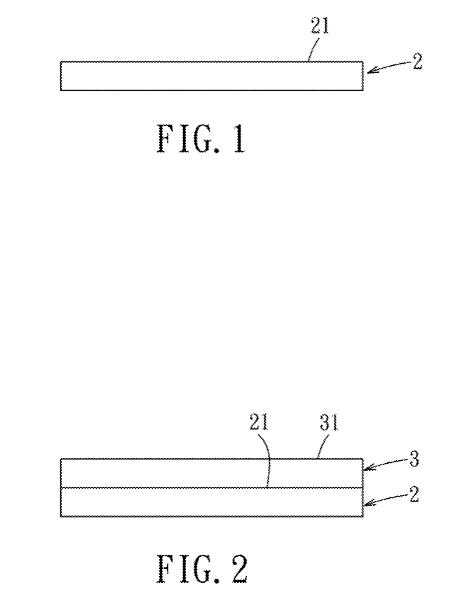

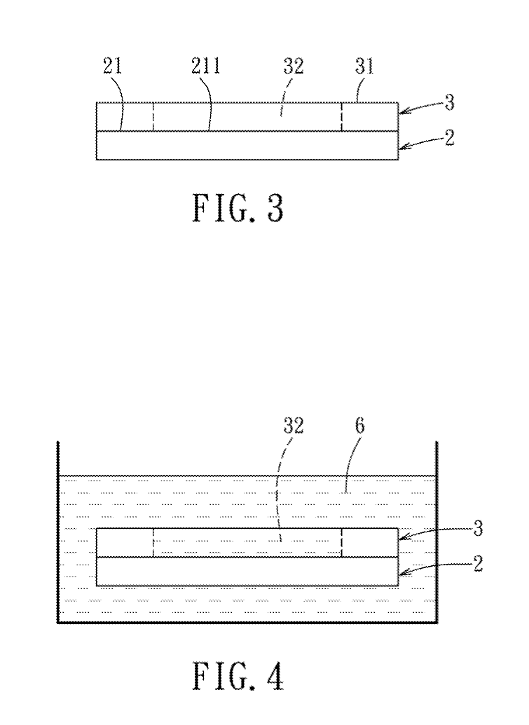

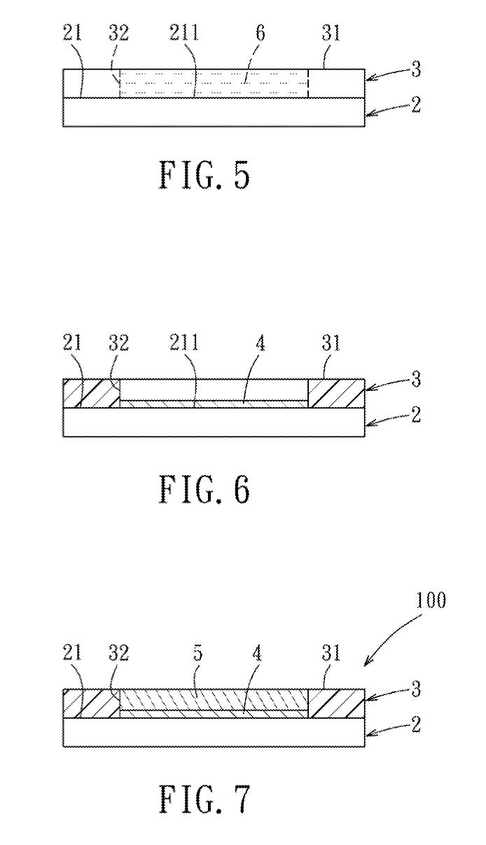

FIGS. 1 to 7 illustrate consecutive steps of the preferred embodiment of a method for making the circuit device 100 according to the present invention. The method includes: forming a hydrophobic anti-plating layer 3 of a hydrophobic material on an upper surface 21 of a substrate 2 (see FIGS. 1 and 2); forming a patterned through-hole 32 in the hydrophobic anti-plating layer 3 by laser ablation such that the patterned through-hole 32 exposes a plating portion 211 of the upper surface 21 of the substrate 2 (see FIG. 3); bringing an assembly of the substrate 2 and the patterned hydrophobic anti-plating layer 3 into contact with an aqueous active metal solution 6 (such as palladium-tin colloid solution) by immersing the assembly into an aqueous active solution bath (see FIG. 4) such that only the plating portion 211 of the upper surface 21 of the substrate 2 is wetted by the aqueous active metal solution 6 (the upper surface 31 of the hydrophobic anti-plating layer 3 is substantially free of the aqueous active metal solution 6 due to a hydrophobic effect provided by the hydrophobic anti-plating layer 3); removing the assembly from the aqueous active solution bath (see FIG. 5), followed by washing with a diluted acid to remove unwanted material, such as tin colloid when palladium-tin colloid solution is used, therefrom, thereby forming an active metal layer 4 on the plating portion 211 of the upper surface 21 of the substrate 2 (see FIG. 6); and electroless depositing an electroless deposited metal layer 5 on the active metal layer 4 (see FIG. 7). Alternatively, the assembly of the substrate 2 and the patterned hydrophobic anti-plating layer 3 can be applied with a promoter layer, such as SnCl layer, followed by immersing the assembly into the aqueous active metal solution 6 (such as PdCl solution) or by spraying the aqueous active metal solution 6 toward the upper surface 31 of the hydrophobic anti-plating layer 3 of the assembly, thereby causing reduction of active metal ions (e.g., palladium ions) into active metal particles (e.g., palladium particles) deposited on the assembly. Since processes of forming an active metal layer on a medium using an active metal solution for subsequent electroless deposition are well known in the art, such as U.S. Pat. Nos. 4,898,648, 5,086,966, and 6,325,910, further details of the same will not be described herein for the sake of brevity

The hydrophobic anti-plating layer 3 preferably has a dark color for facilitating laser ablation.

A preferred example of the aqueous active metal solution 6 is a palladium salt solution having a palladium molarity of 10 to 70 ppm. Since formation of an active metal layer on an insulating substrate using an active metal solution bath for subsequent electroless deposition is well known in the art, reference may be made to U.S. Pat. No. 4,898,648 for the mechanism thereof, further details of the same will not be described herein for the sake of brevity.

The laser ablation of the hydrophobic anti-plating layer 3 is performed using an yttrium aluminum garnet (YAC) laser source under laser parameters including 4 to 10 W laser power, 5 to 30 KHz frequency, and 1 to 7% power density. Since laser ablation techniques are known in the art for patterning a metal layer, reference maybe made to U.S. Pat. No. 4,898, 648 for the mechanism and operation conditions thereof, further details of the same will not be described herein for the sake of brevity.

When a copper chemical plating solution is used for forming the electroless deposited metal layer 5 on the active metal layer 4, the electroless depositing is preferably performed under a temperature ranging from 50 to 55° C. and a processing time ranging from 2 to 5 minutes, and when a nickel chemical plating solution is used, the electroless depositing is preferably performed under a temperature ranging from 40 to 45° C. and a processing time ranging from 2 to 5 minutes.

By using the hydrophobic anti-plating layer 3 in the method of making the circuit device of this invention, the aforesaid drawbacks associated with the prior art may be overcome.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A circuit device comprising:
a substrate having an insulative upper surface;
a hydrophobic anti-plating layer of a hydrophobic material formed on said upper surface of said substrate and having at least one patterned through-hole for exposing a plating portion of said upper surface of said substrate;
an active metal layer formed on said plating portion of said upper surface of said substrate and disposed in said patterned through-hole in said hydrophobic anti-plating layer; and
an electroless deposited metal layer electroless deposited on said active metal layer.

2. The circuit device of claim 1, wherein said hydrophobic anti-plating layer has an upper surface distal from said upper surface of said substrate, said electroless deposited metal layer having an upper surface substantially adjoining said upper surface of said hydrophobic anti-plating layer such that said upper surface of said electroless deposited metal layer and said upper surface of said hydrophobic anti-plating layer cooperatively form a continuous and smooth surface.

3. The circuit device of claim 1, wherein said hydrophobic material is a hydrophobic resin selected from the group consisting of polycarbonate, poly-dimethylsiloxane adipamide, polypropylene, and combinations thereof.

4. The circuit device of claim 1, wherein said hydrophobic material is a hydrophobic resin selected from the group consisting of polycarbonate having a molecular weight ranging from 1000 to 4000, poly-dimethylsiloxane adipamide having a molecular weight ranging from 1000 to 4000, polypropylene having a molecular weight ranging from 1000 to 4000, and combinations thereof.

5. The circuit device of claim 1, wherein said hydrophobic material is made from a wax material.

6. The circuit device of claim 5, wherein said wax material contains a wax and an inorganic oxide selected from the group consisting of silicon dioxide, titanium dioxide, magnesium oxide, zirconium dioxide and combinations thereof.

7. The circuit device of claim 6, wherein said wax material contains 60-95 wt % of said wax and 5-40 wt % of said inorganic oxide.

8. The circuit device of claim 6, wherein said wax has a melting point not less than 60° C.

9. The circuit device of claim 1, wherein said substrate is made from a material selected from the group consisting of polycarbonate, a combination of acryl resin and ABS resin, and a combination of polycarbonate and ABS resin.

10. The circuit device of claim 1, wherein said active metal layer is made from an active material containing an active metal selected from the group consisting of palladium, rhodium, platinum, iridium, osmium, gold, nickel, iron, and combinations thereof.

11. The circuit device of claim 1, wherein said electroless deposited metal layer is made from a metal selected from the group consisting of copper, nickel, silver, and gold.

12. A method for making a circuit device, comprising:
forming a hydrophobic anti-plating layer of a hydrophobic material on an insulative upper'surface of a substrate;
forming a patterned through-hole in the hydrophobic anti-plating layer by laser ablation such that the patterned through-hole exposes a plating portion of the upper surface of the substrate;
bringing an assembly of the substrate and the patterned hydrophobic anti-plating layer into contact with an aqueous active metal solution such that only the plating portion of the upper surface of the substrate is wetted by the aqueous active metal solution, thereby forming an active metal layer on the plating portion of the upper surface of the substrate; and
electroless depositing an electroless deposited metal layer on the active metal layer.

13. The method of claim 12, wherein the bringing of the assembly into contact with the aqueous active metal solution is performed by immersing the assembly into an aqueous active solution bath, followed by removing the assembly from the aqueous active solution bath and washing.

14. The method of claim 12, wherein said hydrophobic material is a hydrophobic resin selected from the group consisting of polycarbonate, poly-dimethylsiloxane adipamide, polypropylene, and combinations thereof.

15. The method of claim 12, wherein said hydrophobic material is a hydrophobic resin selected from the group consisting of polycarbonate having a molecular weight ranging from 1000 to 4000, poly-dimethylsiloxane adipamide having a molecular weight ranging from 1000 to 4000, polypropylene having a molecular weight ranging from 1000 to 4000, and combinations thereof.

16. The method of claim 12, wherein said hydrophobic material is a wax material.

17. The method of claim 16, wherein said wax material contains a wax and an inorganic oxide selected from the group consisting of silicon dioxide, titanium dioxide, magnesium oxide, zirconium dioxide and combinations thereof.

18. The method of claim 17, wherein said wax material contains 60-95 wt % of said wax and 5-40 wt % of said inorganic oxide.

19. The method of claim 17, wherein said wax has a melting point not less than 60° C.

20. The method of claim 12, wherein said substrate is made from a material selected from the group consisting of polycarbonate, a combination of acryl resin and ABS resin, and a combination of polycarbonate and ABS resin.

21. The method of claim 12, wherein said active metal layer is made from an active material containing an active metal selected from the group consisting of palladium, rhodium, platinum, iridium, osmium, gold, nickel, iron, and combinations thereof.

22. The method of claim 12, wherein said electroless deposited metal layer is made from a metal selected from the group consisting of copper, nickel, silver and gold.

23. The method of claim 12, wherein said hydrophobic anti-plating layer has a dark color.
